(19) United States
(12) Patent Application Publication
(10) Pub. No.: US 2010/0124811 A1
(43) Pub. Date: May 20, 2010

(54) Method for fabricating capacitor in semiconductor device

(75) Inventors: Sang-Soo Park, Icheon-si (KR); Jung-Taik Cheong, Icheon-si (KR)

Correspondence Address: LOWE HAUPTMAN HAM & BERNER, LLP, 1700 DIAGONAL ROAD, SUITE 300, ALEXANDRIA, VA, 22314, US

(73) Assignee: Hynix Semiconductor Inc., Icheon-si (KR)

(21) Appl. No.: 12/318,505

(22) Filed: Dec. 30, 2008

(30) Foreign Application Priority Data
Nov. 20, 2008 (KR) 10-2008-0115786

(51) Int. Cl. H01L 21/02

(52) U.S. Cl. 438/386; 257/E21.011

(57) ABSTRACT

A method for fabricating a capacitor in a semiconductor device includes forming a sacrificial layer over a substrate, forming an opening by selectively etching the sacrificial layer, forming a conductive layer for a lower electrode over a whole surface of a resultant structure including the opening, forming the lower electrode by performing a first blanket dry etching process on the conductive layer until the sacrificial layer is exposed, etching the sacrificial layer to a predetermined depth to protrude a top of the lower electrode over the sacrificial layer, and performing a second blanket dry etching process on the lower electrode to remove a hornlike part on top of the lower electrode. Since a blanket dry etching is performed twice, it is possible to easily remove a hornlike part of a lower electrode and prevent a device failure induced by a micro-bridge between adjacent lower electrodes.

### CROSS-REFERENCE TO RELATED APPLICATIONS

The present application claims priority of Korean patent application number 10-2008-0115786, filed on Nov. 20, 2008, which is incorporated herein by reference in its entirety.

### BACKGROUND

The present application relates to a method for fabricating a semiconductor device, and more particularly to a method for fabricating a capacitor in a semiconductor device.

As a semiconductor device is highly integrated, an area occupied by an element included in the semiconductor device such as a transistor or a capacitor has been decreased. For example, a unit cell in Dynamic Random Access Memory (DRAM) device includes one transistor and one capacitor, and an area occupied by the transistor or the capacitor is decreased due to a high integration of the DRAM device. Particularly, a decrease in the area occupied by the capacitor causes a decrease in a capacitance.

Accordingly, various methods for ensuring a sufficient capacitance within a limited area have been suggested. One of the suggested methods is to form a cylinder type capacitor.

FIGS. 1A to 1C are cross-sectional views describing a conventional method for fabricating a cylinder type capacitor.

Referring to FIG. 1A, a first sacrificial layer 11, a supporting layer 12 and a second sacrificial layer 13 are sequentially formed over a substrate 10 including a predetermined underlying structure. Herein, the first sacrificial layer 11 and the second sacrificial layer 13 are formed of an oxide in general. Moreover, the supporting layer 12 is used to prevent a leaning phenomenon, formed of a nitride in general. The leaning phenomenon represents a phenomenon where lower electrodes adjacent to each other are lean over and adhere to each other. As a semiconductor device is highly integrated, an aspect ratio of a lower electrode in a capacitor increases and spaces between lower electrodes decrease so that the leaning phenomenon frequently occurs.

Referring to FIG. 1B, a mask pattern (not shown) defining a region where a lower electrode is to be formed is formed over the second sacrificial layer 13, and then the second sacrificial layer 13, the supporting layer 12 and the first sacrificial layer 11 are etched by using the mask pattern as an etching barrier so that an opening 14 exposing a predetermined part of the substrate 10 is formed. Reference numerals 11A, 12A and 13A represent an etched first sacrificial layer, a supporting layer, and a second sacrificial layer, respectively.

Next, a conductive layer 15 for a lower electrode is formed over a whole surface of a resultant structure including the opening 14. The conductive layer 15 includes TiN in general.

Referring to FIG. 1C, a blanket dry etching process is performed on the conductive layer 15 until the second sacrificial layer 13A is exposed. Therefore, a lower electrode 15A separated from adjacent lower electrodes (not shown) is formed within the opening 14.

Subsequently, although not illustrated, the following conventional processes are performed.

First of all, a portion of the supporting layer 12A is exposed by selectively etching the second sacrificial layer 13A, and then the exposed portion of the supporting layer 12A is removed, thereby forming a patterned supporting layer. The patterned supporting layer is located between the lower electrode 15A and the adjacent lower electrodes, and prevents the leaning phenomenon.

Next, the second sacrificial layer 13A and the first sacrificial layer 11A are removed through a wet dip-out process. The first sacrificial layer 11A added to the second sacrificial layer 13A can be removed through this wet dip-out process because the first sacrificial layer 11A is exposed by removing the portion of the supporting layer 12A in the above process.

Next, a dielectric layer (not shown) and a conductive layer for an upper electrode (not shown) are sequentially formed over a whole surface of a resultant structure, thereby fabricating the cylinder type capacitor.

However, the conventional method for fabricating the cylinder type capacitor has the following problem.

As shown in FIG. 1C, a hornlike part A1 on top of the lower electrode 15A is generated. This is because the blanket dry etching process on the conductive layer 15 is performed under the condition that the selectivity between the conductive layer 15 and the second sacrificial layer 13A is high.

If the hornlike part A1 is generated, the top of the lower electrode 15A with the hornlike part A1 is broken while the second sacrificial layer 13A and the first sacrificial layer 11A are removed through a wet dip-out process. The broken part is formed of a conductive material so that defects such as a micro-bridge between adjacent lower electrodes may be caused, and consequentially, a failure of a device may occur.

FIGS. 2A and 2B are photographs showing a conventional cylinder type capacitor with a failure. Particularly, FIG. 2A shows an analyzed result of a focused ion beam (FIB) and FIG. 2B is a photograph showing a cross-section of the cylinder type capacitor with a failure shown in FIG. 2A.

Referring to FIGS. 2A and 2B, the device failure is induced by a micro-bridge between adjacent lower electrodes that occurs when a hornlike part of the lower electrode is broken and laid on a supporting layer.

### SUMMARY

Some embodiments are directed to a method for fabricating a capacitor in a semiconductor device which is capable of easily removing a hornlike part of a lower electrode and preventing a device failure induced by a micro-bridge between adjacent lower electrodes.

In accordance with one or more embodiments, there is provided a method for fabricating a capacitor in a semiconductor device including: forming a sacrificial layer over a substrate; forming an opening by selectively etching the sacrificial layer; forming a conductive layer for a lower electrode over a whole surface of a resultant structure including the opening; forming the lower electrode by performing a first blanket dry etching process on the conductive layer until the sacrificial layer is exposed; etching the sacrificial layer to a predetermined depth to protrude a top of the lower electrode over the sacrificial layer; and performing a second blanket dry etching process on the lower electrode to remove a hornlike part on top of the lower electrode.

### BRIEF DESCRIPTION OF THE DRAWINGS

FIGS. 1A to 1C are cross-sectional views describing a conventional method for fabricating a cylinder type capacitor.

FIGS. 2A and 2B are photographs showing a conventional cylinder type capacitor with a failure.

FIGS. 3A to 3E are cross-sectional views describing a method for fabricating a cylinder type capacitor in accordance with an embodiment.

FIGS. 4A and 4B are photographs for comparing a shape of a lower electrode fabricated through a conventional method with a shape of a lower electrode fabricated through a method in accordance with the embodiment.

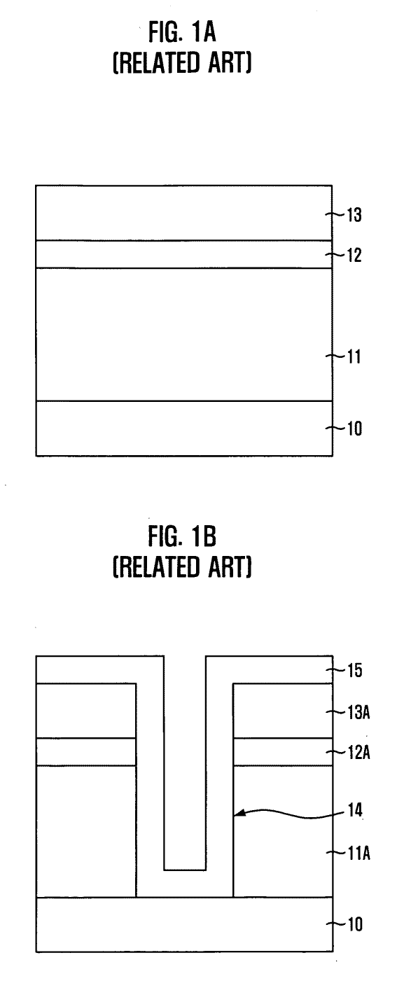

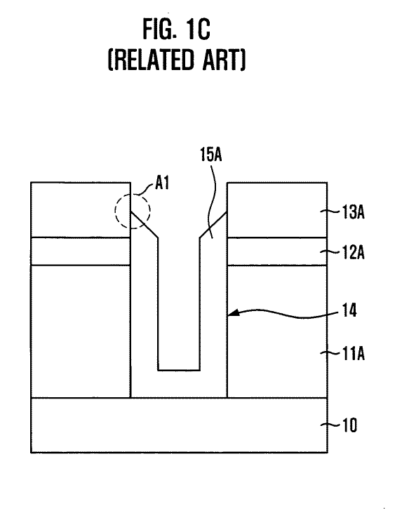

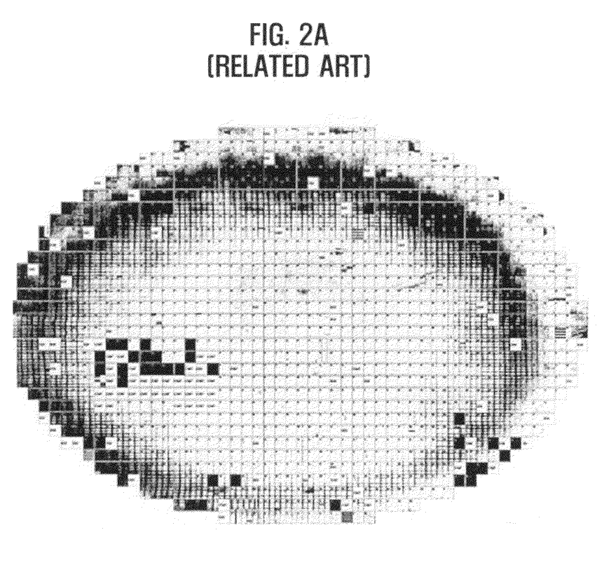

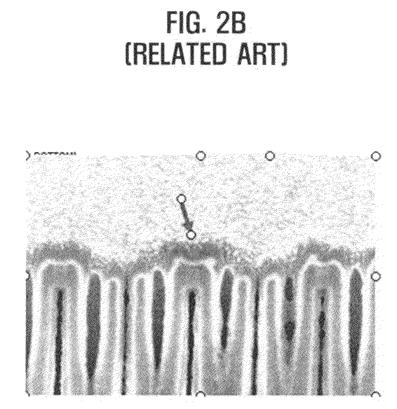

### DESCRIPTION OF EMBODIMENTS

Hereinafter, a method for fabricating a capacitor in a semiconductor device in accordance with one or more embodiments will be described in detail with reference to the accompanying drawings.

In the figures, the dimensions of layers and regions are exaggerated for clarity of illustration. It will also be understood that when a layer is referred to as being “on/under” another layer or substrate, it can be directly on/under the other layer or substrate, or intervening layers may also be present. Like reference numerals refer to like elements throughout the drawings. In addition, changes to the English characters of the reference numerals of layers refer to a partial deformation of the layers by an etch process or a polishing process.

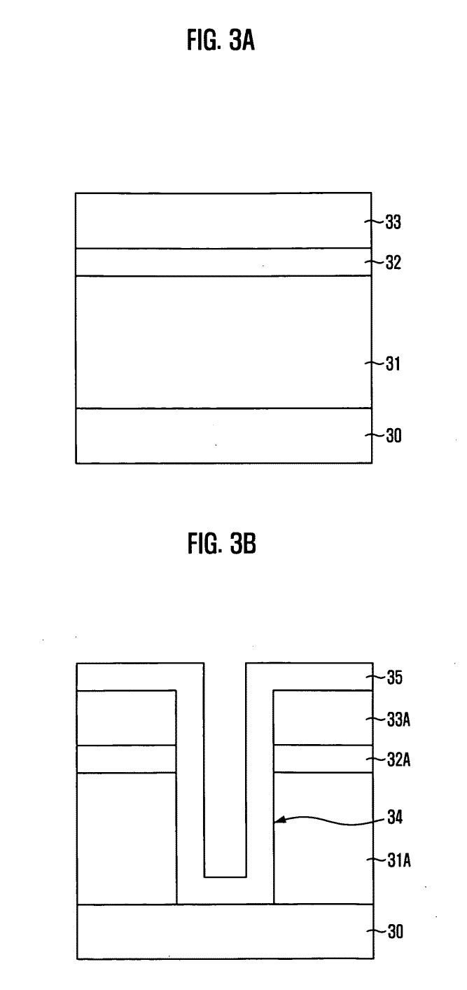

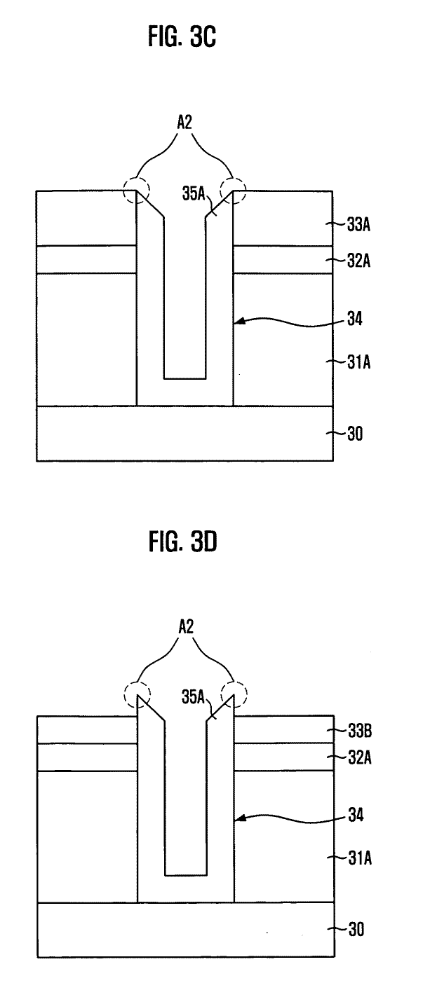

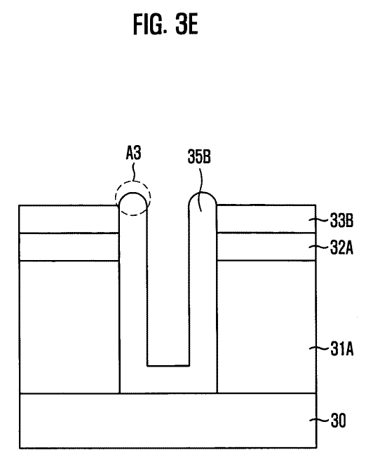

FIGS. 3A to 3E are cross-sectional views describing a method for fabricating a cylinder type capacitor in accordance with an embodiment.

Referring to FIG. 3A, a first sacrificial layer 31, a supporting layer 32 and a second sacrificial layer 33 are sequentially formed over a substrate 30 including a predetermined underlying structure. Herein, the first sacrificial layer 31 and the second sacrificial layer 33 may be formed of an oxide. Moreover, the supporting layer 32 is used to prevent a leaning phenomenon and may be formed of a nitride.

Referring to FIG. 3B, a mask pattern (not shown) defining a region where a lower electrode is to be formed is formed over the second sacrificial layer 33, and then the second sacrificial layer 33, the supporting layer 32 and the first sacrificial layer 31 are etched by using the mask pattern as an etching barrier so that an opening 34 exposing a predetermined part of the substrate 30 is formed. Reference numerals 31A, 32A and 33A represent an etched first sacrificial layer, a supporting layer, and a second sacrificial layer, respectively.

Next, a conductive layer 35 for a lower electrode is formed over a whole surface of a resultant structure including the opening 34. The conductive layer 35 may include TiN.

Referring to FIG. 3C, a first blanket dry etching process is performed on the conductive layer 35 until the second sacrificial layer 33A is exposed. At this time, a time of the first blanket dry etching process on the conductive layer 35 is shorter than that of a conventional method. Therefore, an initial lower electrode 35A separated from adjacent lower electrodes (not shown) is formed within the opening 34, having a height greater than that of the conventional method. In this case, as described above, a hornlike part A2 on top of the initial lower electrode 35A is generated because of a high selectivity between the conductive layer 35 and the second sacrificial layer 33A.

When the conductive layer 35 includes TiN, the first blanket dry etching process may be performed at a pressure ranging from approximately 6 mT to approximately 8 mT, a top power ranging from approximately 350 W to approximately 450 W, and a bias power ranging from approximately 90 W to approximately 110 W with Ar having a flow rate of approximately 150 sccm to approximately 170 sccm and Cl₂ having a flow rate of approximately 26 sccm to approximately 30 sccm.

Referring to FIG. 3D, the second sacrificial layer pattern 33B is formed by etching the second sacrificial layer 33A to a predetermined depth. Consequently, the hornlike part A2 on top of the initial lower electrode 35A protrudes over the second sacrificial layer pattern 33B.

When the second sacrificial layer 33A is formed of an oxide, the etching process on the second sacrificial layer 33A may be performed at a pressure ranging from approximately 9 mT to approximately 11 mT and a top power ranging from approximately 190 W to approximately 210 W with Ar having a flow rate of approximately 160 sccm to approximately 180 sccm and a F (fluorine) based gas such as CHF₃ having a flow rate of approximately 28 sccm to approximately 32 sccm.

Meanwhile, in the above process described in FIG. 3D, if the conductive layer 35 includes TiN, the second sacrificial layer 33A is formed of an oxide and the etching process on the second sacrificial layer 33A is performed using the F-based gas, TiF polymers are generated through a reaction between Ti and F. Particularly, these TiF polymers are concentrated to the hornlike part A2 of the initial lower electrode 35A to thereby function as an obstruction in the following process for removing the hornlike part A2.

Therefore, it is desirable to perform an additional Post Etching Treatment (PET) process between the etching process on the second sacrificial layer 33A and the process for removing the hornlike part A2. The PET process may be performed at a pressure ranging from approximately 13 mT to approximately 17 mT, a top power ranging from approximately 350 W to approximately 450 W, and a bias power ranging from approximately 90 W to approximately 110 W with O₂ having a flow rate of approximately 180 sccm to approximately 220 sccm.

Referring to FIG. 3E, a second blanket dry etching process is performed on the initial lower electrode 35A. At this time, the hornlike part A2 of the initial lower electrode 35A is mainly etched because the hornlike part A2 protrudes over an area around it. Consequently, the hornlike part A2 is removed so that a final lower electrode 35B whose top has a hornless shape (e.g., a round shape) A3 is formed.

The second blanket dry etching process may be performed under a condition same as or similar to the first blanket dry etching process. For example, the second blanket dry etching process may be performed at a pressure ranging from approximately 6 mT to approximately 8 mT, a top power ranging from approximately 350 W to approximately 450 W, and a bias power ranging from approximately 90 W to approximately 110 W with Ar having a flow rate of approximately 150 sccm to approximately 170 sccm and Cl₂ having a flow rate of approximately 26 sccm to approximately 30 sccm. On the other hand, a time of the second blanket dry etching process is shorter than that of the first blanket dry etching process. Because it is only needed to remove the hornlike part A2 of the initial lower electrode 35A in the second blanket dry etching process.

Next, although not illustrated, the following processes are performed.

First of all, a portion of the supporting layer 32A is exposed by selectively etching the second sacrificial layer pattern 33B, and then the exposed portion of the supporting layer 32A is removed, thereby forming a patterned supporting layer. The patterned supporting layer is located between lower electrodes including the final lower electrode 35B, and prevents the leaning phenomenon.

Next, the second sacrificial layer pattern 33B and the first sacrificial layer 31A are removed through a wet dip-out process. At this time, the top of the final lower electrode 35B is not broken in spite of the wet dip-out process because of having a hornless shape A3.

Next, a dielectric layer (not shown) and a conductive layer for an upper electrode (not shown) are sequentially formed over a whole surface of a resultant structure, thereby fabricating the cylinder type capacitor.

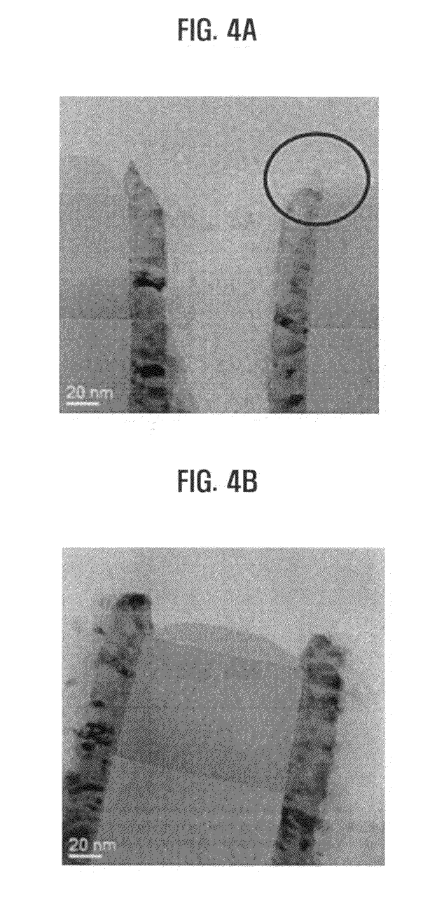

FIGS. 4A and 4B are photographs for comparing a shape of a lower electrode fabricated through a conventional method with a shape of a lower electrode fabricated through a method in accordance with the embodiment.

Referring to FIG. 4A, a top of the lower electrode fabricated through the conventional method has a hornlike shape.

On the other hand, referring to FIG. 4B, a top of the lower electrode fabricated through the method in accordance with the embodiment has a hornless shape.

The method for fabricating a capacitor in a semiconductor device in accordance with the embodiment as described above can easily remove a hornlike part of a lower electrode and prevent a device failure induced by a micro-bridge between adjacent lower electrodes.

The above embodiment is illustrative and not limitative. It will be apparent to those skilled in the art that various changes and modifications may be made without departing from the spirit and scope as defined in the following claims.

For example, a structure where a first sacrificial layer, a supporting layer and a second sacrificial layer are stacked is shown in the above embodiment, but this is not restrictive, the supporting layer may be skipped.

What is claimed is:

1. A method for fabricating a capacitor in a semiconductor device, the method comprising:
forming a sacrificial layer over a substrate;
forming an opening by selectively etching the sacrificial layer;
forming a conductive layer for a lower electrode over a whole surface of a resultant structure including the opening;
forming the lower electrode by performing a first blanket dry etching process on the conductive layer until the sacrificial layer is exposed;
etching the sacrificial layer to a predetermined depth to protrude a top of the lower electrode over the sacrificial layer; and
performing a second blanket dry etching process on the lower electrode to remove a hornlike part on top of the lower electrode.

2. The method of claim 1, further comprising:
performing a Post Etching Treatment (PET) process to remove polymers generated during the etching the sacrificial layer to the predetermined depth after the etching the sacrificial layer to the predetermined depth.

3. The method of claim 1, wherein the sacrificial layer is formed of an oxide.

4. The method of claim 1, wherein the conductive layer includes TiN.

5. The method of claim 1, wherein the sacrificial layer is formed of an oxide and the conductive layer includes TiN.

6. The method of claim 4, wherein the first blanket etching process or the second blanket etching process is performed at a pressure ranging from approximately 6 mT to approximately 8 mT, a top power ranging from approximately 350 W to approximately 450 W, and a bias power ranging from approximately 90 W to approximately 110 W with Ar having a flow rate of approximately 150 sccm to approximately 170 sccm and Cl₂ having a flow rate of approximately 26 sccm to approximately 30 sccm.

7. The method of claim 3, wherein the etching the sacrificial layer to the predetermined depth is performed at a pressure ranging from approximately 9 mT to approximately 11 mT and a top power ranging from approximately 190 W to approximately 210 W with Ar having a flow rate of approximately 160 sccm to approximately 180 sccm and a F (fluorine) based gas having a flow rate of approximately 28 sccm to approximately 32 sccm.

8. The method of claim 5, further comprising:
performing a PET process to remove TiF polymers generated during the etching the sacrificial layer to the predetermined depth after the etching the sacrificial layer to the predetermined depth,
wherein the etching the sacrificial layer to the predetermined depth is performed using a F-based gas.

9. The method for claim 8, wherein the PET process is performed at a pressure ranging from approximately 13 mT to approximately 17 mT, a top power ranging from approximately 350 W to approximately 450 W, and a bias power ranging from approximately 90 W to approximately 110 W with O₂ having a flow rate of approximately 180 sccm to approximately 220 sccm.

10. The method for claim 1, wherein a time of the second blanket dry etching process is shorter than a time of the first blanket dry etching process.

11. The method for claim 1, further comprising:
removing the sacrificial layer by performing a wet dip-out process after the performing the second blanket dry etching process

12. The method for claim 1, wherein the sacrificial layer includes a structure where a first sacrificial layer and a second sacrificial layer are stacked, and a supporting layer is interposed between the first sacrificial layer and the second sacrificial layer.
